(19) United States
(12) Patent Application Publication
(10) Pub. No.: US 2004/0053079 A1
(43) Pub. Date: Mar. 18, 2004

(54) High-temperature superconducting device

(75) Inventors: Masahiro Horibe, Zama-shi (JP); Yoshihiro Ishimaru, Yokohama-shi (JP); Osami Horibe, Tokyo (JP); Keiichi Tanabe, Mito-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: FUJITSU LIMITED, Kawasaki (JP); INTERNATIONAL SUPERCONDUCTIVITY TECHNOLOGY CENTER, Tokyo (JP)

(21) Appl. No.: 10/634,808

(22) Filed: Aug. 6, 2003

(30) Foreign Application Priority Data
Aug. 8, 2002 (JP) 2002-230848

(51) Int. Cl. B32B 1/00; H01F 6/00; H01B 12/00; H01L 39/00; B32B 9/00; B32B 19/00

(52) U.S. Cl. 428/701; 428/930; 505/237; 505/238

(57) ABSTRACT

A high temperature superconducting device includes a substrate (1), a ground plane (2) formed on the substrate with a prescribed pattern and made of an oxidic superconducting material, and a dielectric layer (3) formed on the substrate so as to surround the ground plane. The dielectric layer has the same crystal structure as the oxidic superconducting material and with a heat absorbance closer to that of the oxidic superconducting material than to that of the substrate.

### CROSS REFERENCE TO RELATED APPLICATIONS

This patent application is based on and claims the benefit of the earlier filing date of Japanese Patent Application No. 2002-230848 filed Aug. 8, 2002, the entire contents of which are incorporated herein by reference.

### BACKGROUND OF THE INVENTION

1. Field of the Invention

The present invention generally relates to a high-temperature superconducting device, and more particularly to a high-temperature superconducting device with a structure for reducing variation in a superconducting junction due to difference in heat absorbance between the ground plane and the substrate used in a high-temperature superconducting circuit.

2. Description of the Related Art

In recent years, superconducting circuit devices, which operate at high speed and have low power consumption, have been attracting a great deal of attention. In realizing such superconducting circuit devices, a layering technique for fabricating a layered structure, including a ground plane, is required, in addition to a junction forming technique.

FIG. 1A and FIG. 1B illustrate a SQUID (Superconducting Quantum Interference Device), which is a typical example of the superconducting circuit device. FIG. 1A is a plan view of the SQUID, and FIG. 1B is a cross-sectional view of the SQUID, showing a Josephson junction as an essential component of the SQUID. Ground plane 42 made of YBCO (YBa₂Cu₃O₇₋ₓ) and with a thickness of 1 μm or less is formed over the single crystalline MgO substrate 41, using laser ablation. Moat 43 is formed in the ground plane 42.

Several moats (four, in the example shown in FIG. 1A) 43 are arranged so as to surround the superconducting junction 50, as illustrated in FIG. 1A.

Then, a first interlevel dielectric 44 made of LSAT ((LaSrAl)TaO₃) and having a thickness of, for example, 200 nm is formed using laser ablation. A contact hole 45 is formed in the first interlevel dielectric 44 so as to reach the ground plane 42. Then, a YBCO layer with a thickness of 200 nm is deposited, which is then patterned into a YBCO bottom electrode 46 by ion milling.

Then, a second interlevel dielectric 48 made of LSAT and having a thickness of, for example, 300 nm is formed. An opening is formed in the second interlevel dielectric 48 so as to expose the top face of the YBCO bottom electrode 46. The exposed top surface of the YBCO bottom electrode 46 is irradiated by argon (Ar) ions. The irradiation of Ar ions damages and degrades the YBCO, thereby producing a YBCO surface-modified barrier 47. A contact hole for a plug electrode 51 is also formed in the second interlevel dielectric 48 so as to reach the bottom electrode 46.

Then, a YBCO layer with a thickness of 400 nm is formed over the entire surface, which is patterned by ion milling to form the YBCO top electrode 49 and the plug electrode 51.

In this structure, the YBCO top electrode 49, the YBCO surface-modified barrier 47, and the YBCO bottom electrode 46 form a superconducting junction 50 that constitutes a Josephson junction.

The plug electrode 51 has an opening for receiving Au resistant layer 52.

Gold (Au) is deposited over the entire surface, and patterned into an Au resistant layer 52, which is connected in series to the plug electrode 51. In this manner, the basic structure of the superconducting circuit device is completed.

Since the superconducting circuit device deals with high-speed signals, the ground plane 42 that is indispensable for circuit operation becomes a drawback to the input/output section connected to the external circuit, from the viewpoint of floating capacitance and matching of impedance.

To overcome this problem, the ground plane is patterned so as to remove a portion thereof at the input/output section connected to the external circuit. Removing a portion of the ground plane causes a difference in level of the surface of the oxide substrate, depending on the presence or absence of the ground plane.

Such a difference in level causes a defect to be produced in the high-temperature superconducting film formed on the ground plane, and consequently, superconducting characteristics, such as critical electric current density, is degraded. To prevent this drawback, it is proposed to bury the supercondunciting ground plane in the oxide substrate to eliminate the level difference. (Presented at the 13^{th} International Symposium on Superconductivity, ISS 2000, with the presentation unpublished.)

However, forming a buried superconducting ground plane in the oxide substrate causes another problem. While the oxide substrate is transparent or semitransparent, the embedded superconducting thin film is dark. For this reason, when depositing superconducting or dielectric material on the oxide substrate with a buried superconducting ground plane, a temperature distribution is generated on the surface of the substrate due to the difference in heat absorbance between the oxide substrate and the superconducting ground plane.

In addition, the surface temperature of the substrate also fluctuates depending on the pattern density of the ground plane.

Such fluctuation or temperature distribution results in variation in physical or electrical characteristics of the thin films and the superconducting junction deposited on and fabricated over the oxide substrate with the buried ground plane, respectively.

Because the deposition condition on the oxide substrate (such as the MgO substrate) differs from that on the ground plane of the superconducting material (such as YBCO), the characteristic of the thin film formed over them varies within a plane when there is a two-dimensional temperature distribution existing on the surface of the substrate. For example, when forming a superconducting thin film over the substrate with the buried ground plane, the critical electrical current density, the critical temperature, the inductance, and the crystal orientation (depending on the situation) vary within the plane. If a dielectric layer is formed over the substrate with the buried ground plane, then the dielectric characteristic and the crystal orientation vary on the substrate.

The above-described problem of the temperature distribution due to the two-dimensional arrangement of the ground plane occurs even if the ground plane is formed over the substrate, instead of being buried in the substrate.

### SUMMARY OF THE INVENTION

Therefore, it is an object of the present invention to reduce the temperature distribution generated in the surface of the substrate due to the two-dimensional arrangement of the ground plane.

FIG. 2 illustrates the basic idea of the present invention. With reference to FIG. 2, how the above-described problem is overcome in the present invention is explained below.

In a high-temperature superconducting device, a dielectric layer 3 is provided so as to surround the ground plane 2 made of an oxidic superconducting material and formed on the substrate 1. The dielectric layer 3 has the same crystal structure as the oxidic superconducting material and has a heat absorbance closer to the oxidic superconducnting material than to the substrate 1. The ground plane 2 is embedded in this dielectric layer 3.

By setting the heat absorbance of the dielectric layer 3 in which the ground plane 2 is embedded closer to that of the oxidic superconducting material of the ground plane 2 than to that of the substrate 1, the temperature distribution on the surface of the substrate 1 can be reduced during the film formation. Consequently, undesirable variations in physical or electrical characteristics of the thin films or the superconducting junction deposited on or fabricated over the substrate 1, respectively, can be reduced.

By selecting a crystal structure of the dielectric layer so as to be the same as that of the oxidic superconducting material, a film (e.g., an interlevel dielectric) can be formed over the dielectric layer 3 and the ground plane 2 under the similar conditions of film deposition. Consequently, a film (or interlevel dielectric) with a uniform crystalline characteristic can be formed over the entire surface.

In addition, since the hardness of the dielectric material becomes almost the same as that of the oxidic superconducting material, a flat surface can be obtained in the polishing process for planarization, while preventing excessive removal of one material.

The embedded ground plane 2 may be formed by providing the dielectric layer 3 having a recess of a prescribed pattern on the substrate 1, and then filling the recess with an oxidic superconducting material. This forming method can equally achieve the same function and effect as those described above.

In another method, an oxidic superconducting material is filled in a recess formed in the substrate 1 so as to exceed the depth of the recess, and a dielectric layer 3 is formed on the substrate in the area other than the recess. The crystal structure of the dielectric material is similar to that of the oxidic superconducting material, and the heat absorbance of the dielectric material is closer to that of the oxidic superducting material than to that of the substrate 1.

The ground plane 2 does not have to have an embedded structure. For example, the ground plane 2 may be formed on the dielectric layer 3 that is formed over the entire surface of the substrate 1. By arranging the ground plane 2 on the dielectric layer 3 covering the substrate 1, the temperature distribution on the surface of the substrate 1 can be reduced during the film formation.

A preferred example of the oxidic superconducting material for the ground plane 2 includes, but is not limited to, XBa₂Cu₃O₇₋ₓ, where X is selected from a group consisting of yttrium (Y), a lanthanoid element except for praseodymium (Pr) and cerium (Ce), and a combination of multiple lanthanoid elements except for Pr and Ce. Preferred examples of the dielectric material includes, but are not limited to, PrBa₂Cu₃O₇₋ₓ, having the same perovskite structure as XBa₂Cu₃O₇₋ₓ, and an additive-containing PrBa₂Cu₃O₇₋ₓ containing, for example, gallium (Ga) or cobalt (Co).

Alternatively, a bismuth (Bi) compound layered crystal oxidic superconductor may be used as the oxide superconductor. In this case, the dielectric layer is formed of a bismuth (Bi) compound layered crystal dielectric material.

Since the deposition conditions of the oxidic superconductor and the dielectric material having the same crystal structure as the oxidic superconductor are very similar to each other, the above-described ground plane structure can be achieved, regardless of the type of the substrate 1. Accordingly, the substrate 1 may be made of any suitable oxidic material, such as MgO, SrTiO₃, or [LaAlO₃]_{0.3}[Sr(Al, Ta)O₃]_{0.7}.

The substrate 1 is not limited to these oxidic materials. For example, a layered substrate, in which any one of a MgO film, a SrTiO₃ film, and a [LaAlO₃]_{0.3}[Sr(Al, Ta)O₃]_{0.7} film is deposited on a single crystalline silicon (Si) substrate, may be used. Such a layered substrate can achieve the same effect.

### BRIEF DESCRIPTION OF THE DRAWINGS

Other objects, features, and advantages of the present invention will become more apparent from the following detailed description when read in conjunction with the accompanying drawings, in which:

FIG. 1A and FIG. 1B illustrate the structure of a conventional superconducting circuit device;

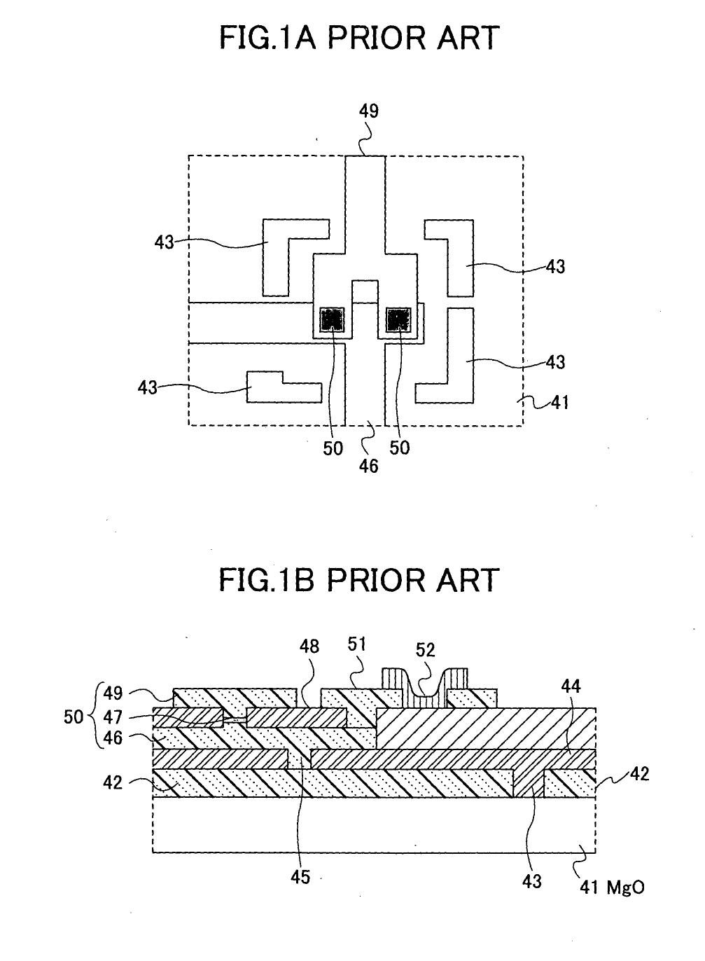

FIG. 2 illustrates the basic idea of the present invention;

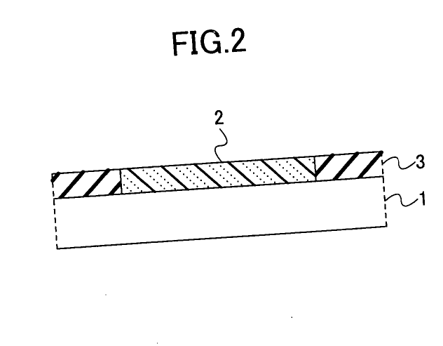

FIG. 3A through FIG. 3G illustrate a fabrication process of the ground plane according to the first embodiment of the invention;

FIG. 4A through FIG. 4G illustrate a fabrication process of the ground plane according to the second embodiment of the invention;

FIG. 5 illustrates the structure of the ground plane according to the third embodiment of the invention;

FIG. 6 illustrates the structure of the ground plane according to the fourth embodiment of the invention; and

FIG. 7 illustrates the structure of the ground plane according to the fifth embodiment of the invention.

### DETAILED DESCRIPTION OF THE PREFERED EMBODIMENTS

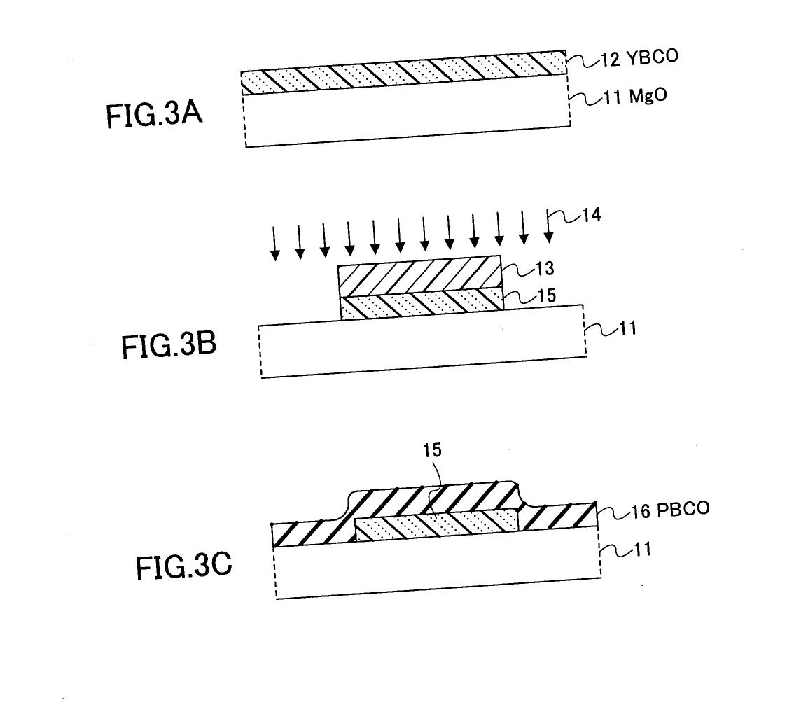

FIG. 3A through FIG. 3G illustrate a fabrication process of the ground plane according to the first embodiment of the invention.

As illustrated in FIG. 3A, a YBCO layer 12 with a composition of YBa₂Cu₃O₇₋ₓ is formed on the MgO substrate 11. The thickness of the YBCO layer 12 is 1 μm or less, and in this example, it is set to 300 nm.

Then, as illustrated in FIG. 3B, photoresist is applied onto the entire surface, and a resist pattern 13 is formed through exposure and development. Using this resist pattern 13 as a mask, the YBCO layer 12 is patterned into a ground plane 15 with a predetermined two-dimensional shape, by ion milling using argon (Ar) ions 14.

Then, as illustrated in FIG. 3C, the resist pattern 13 is removed, and a PBCO layer 16 with a composition of PrBa₂Cu₃O₇₋ₓ, and a thickness of 300 nm is formed over the entire surface by sputtering. Since the conditions for film deposition of PBCO on the MgO substrate 11 and on the YBCO ground plane 15 are substantially the same, a PBCO layer 16 can be formed with a uniform characteristic across the entire area.

PBCO has the same perovskite crystal structure as YBCO, and it is as dark as YBCO with a similar heat absorbance.

Then, as illustrated in FIG. 3D, photoresist is applied onto the entire surface, which is then exposed and developed to form a resist mask pattern 17. The resist mask pattern 17 has an opening smaller than the ground plane 15. Using the resist mask pattern 17, ion milling is performed with argon (Ar) ions 18 to remove the exposed part of the PBCO layer 16 deposited on the ground plane 15.

Then, as illustrated in FIG. 3E, the resist mask pattern 17 is removed. A wall 19 remains around the ground plane 15 after the removal of the resist mask pattern 17 because of the size difference between the opening of the resist mask pattern 17 and the ground plane 15.

Then, as illustrated in FIG. 3F, the wall 19 is removed by polishing using aluminum grains, and the surface is planarized to form a PBCO dielectric 20 surrounding the buried ground plane 15.

The hardness of the YBCO ground plane 15 and that of the PBCO dielectric 20 are substantially the same, and therefore, surface planarization is carried out satisfactorily, without degradation, even if slightly excessive polishing is performed.

Then, as illustrated in FIG. 3G, the substrate 11 with the buried ground plane 15 and the PBCO dielectric 20 is immersed in a cleaning solution 21 (to be more precise, in a xylene rinsing solution, and then in an ethanol rinsing solution), to perform ultrasonic cleaning for five minutes in each solution in order to remove the polishing grains from the surface.

In the subsequent process, formation of an interlevel dielectric (not shown), such as LSAT, and formation of an oxidic superconducting layer (not shown), such as a YBCO layer, are repeated in accordance with the designed structure of the superconducting circuit.

Both YBCO, which is a material of the buried ground plane 15, and PBCO, which is a material of the dielectric 20 surrounding the ground plane 15, have a dark color with almost the same heat absorbance, and the surface temperature distribution during fabrication can be reduced. Accordingly, the crystal characteristic and the electrical characteristic of an interlevel dielectric (not shown), such as LSAT, formed on the YBCO ground plane 15 and the PBCO dielectric 20 can be maintain uniform across the entire area. Similarly, the crystal characteristic and the electrical characteristic of an oxidic superconducting thin film (not shown), such as a YBCO thin film, formed on the interlevel dielectric (not shown) above the YBCO buried ground plane 15 and the PBCO dielectric 20 can be made uniform across the area.

Thus, the substrate with the buried ground plane according to the first embodiment of the invention can prevent two-dimensional variation in crystal characteristics and electric characteristics of layers formed on or above the substrate, caused by difference in deposition condition due to difference in heat absorbance. Accordingly, variation or non-uniformity at the superconducting junction fabricated by those layers deposited on the substrate can be reduced.

Furthermore, providing the buried ground plane can reduce the unevenness of the surface, and can prevent degradation of the dielectric characteristic of the interlevel dielectric (not shown), and breakdown or degradation of the superconducting interconnect layer, deposited over the ground plane.

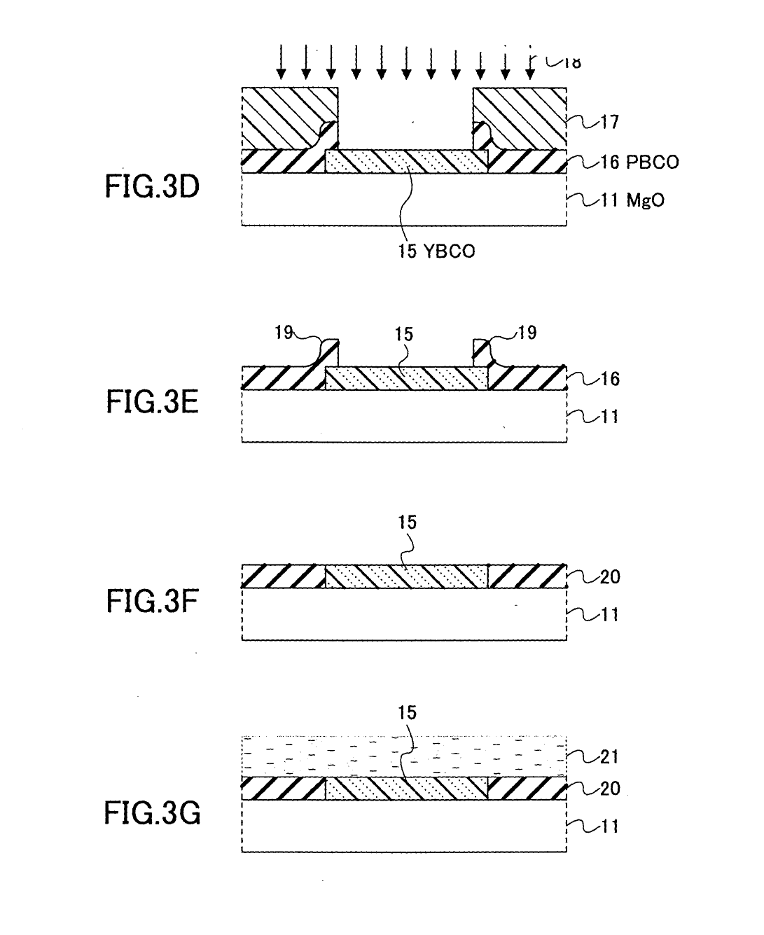

FIG. 4A through FIG. 4G illustrate a fabrication process of the ground plane according to the second embodiment of the invention.

As illustrated in FIG. 4A, a PBCO layer 16 with a composition of PrBa₂Cu₃O₇₋ₓ is formed on the MgO substrate 11. The thickness of the PBCO layer 16 is 300 nm in this example.

Then, as illustrated in FIG. 4B, photoresist is applied onto the entire surface, and a resist pattern 22 is formed through exposure and development. Using this resist pattern 22 as a mask, a recess 24 with a depth of 300 nm is formed in the PBCO layer 22 by ion milling using argon (Ar) ions 23. The shape of the recess 24 corresponds to that of the ground plane to be fabricated.

Then, as illustrated in FIG. 4C, the resist pattern 22 is removed, and a YBCO layer 12 with a composition of YBa₂Cu₃O₇₋ₓ and a thickness of 300 nm is formed over the entire surface by sputtering.

Since the conditions for film deposition of YBCO layer on the MgO substrate 11 and on the PBCO layer 16 are substantially the same, the YBCO layer 12 can be formed with a uniform quality across the entire area.

PBCO has the same perovskite crystal structure as YBCO, and it is as dark as YBCO with a similar heat absorbance.

Then, as illustrated in FIG. 4D, photoresist is applied onto the entire surface, which is then exposed and developed to form a resist mask pattern 25. This resist mask pattern 25 is slightly larger than the size of the recess 24. Using the resist mask pattern 25, ion milling is performed with argon (Ar) ions 26 to remove the YBCO layer 12 deposited on the PBCO layer 16 in the area other than the above slightly larger area including recess 24.

Then, as illustrated in FIG. 4E, the resist mask pattern 25 is removed. A wall 27 remains around the recess 24 after the removal of the resist mask pattern 25 because of the size difference between the resist mask pattern 25 and the recess 24.

Then, as illustrated in FIG. 4F, the wall 27 is removed by polishing using aluminum grains, and the surface is planarized to form a buried YBCO layer 15.

The hardness of the YBCO ground plane 15 and that of the PBCO layer 16 are substantially the same, and therefore, surface planarization is carried out satisfactorily, without degradation, even if slightly excessive polishing is performed.

Then, as illustrated in FIG. 4G, the substrate 11 with the ground plane 15 buried in the PBCO layer 16 is immersed in a cleaning solution 21. To be more precise, the substrate 11 is immersed in a xylene rinsing solution, and then in an ethanol rinsing solution, to perform ultrasonic cleaning for five minutes in each solution in order to remove the polishing grains from the surface.

In the subsequent process, formation of an interlevel dielectric (not shown), such as LSAT, and formation of an additional oxidic superconducting layer (not shown), such as a YBCO layer, are repeated in accordance with the designed structure of the superconducting circuit.

With the buried ground plane structure according to the second embodiment, the film deposition conditions for interlevel dielectric, such as LSAT, and for oxidic superconducting layer, such as YBCO, in the subsequent process become substantially the same, as in the first embodiment. Therefore, the same effects and advantages as in the first embodiment can be achieved.

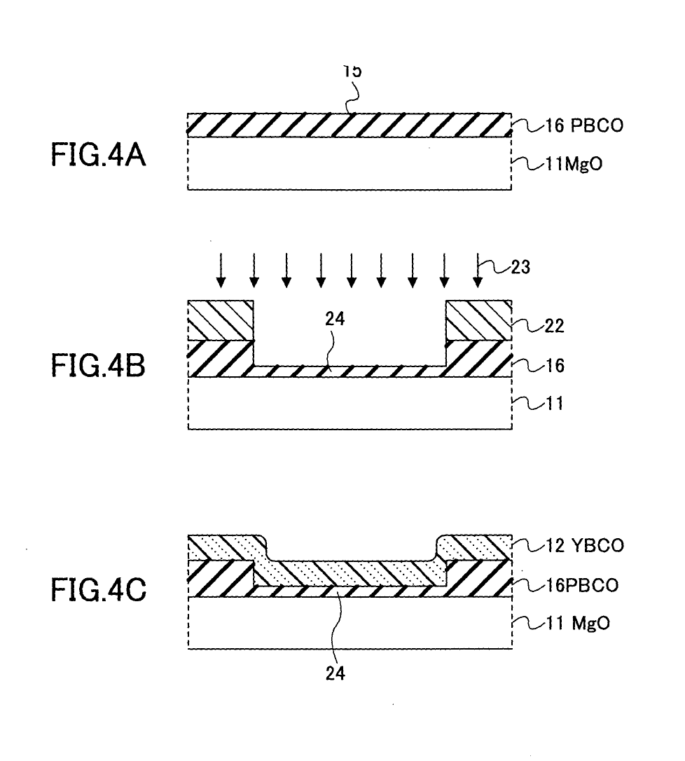

FIG. 5 illustrates the ground plane according to the third embodiment of the invention.

As illustrated in the cross-sectional view of FIG. 5, the ground plane 15 is buried in the MgO substrate 11, and surrounded by the PBCO thin film 28. To fabricate this ground plane structure, the PBCO thin film 28 with a thickness of 100 nm is formed over the MgO substrate 11 by sputtering. Then, a recess is formed by removing a portion of the PBCO thin film 28 and the MgO substrate 11 through argon (Ar) ion milling, using a resist mask pattern (not shown). Then, the steps shown in FIG. 4C through 4G illustrated in the second embodiment are performed to fabricate the buried ground plane 15.

With the buried ground plane structure according to the third embodiment, the film deposition conditions for interlevel dielectric, such as LSAT, and for oxidic superconducting layer, such as YBCO, in the subsequent process become substantially the same as in the first embodiment. Therefore, the same effects and advantages as in the first embodiment can be achieved.

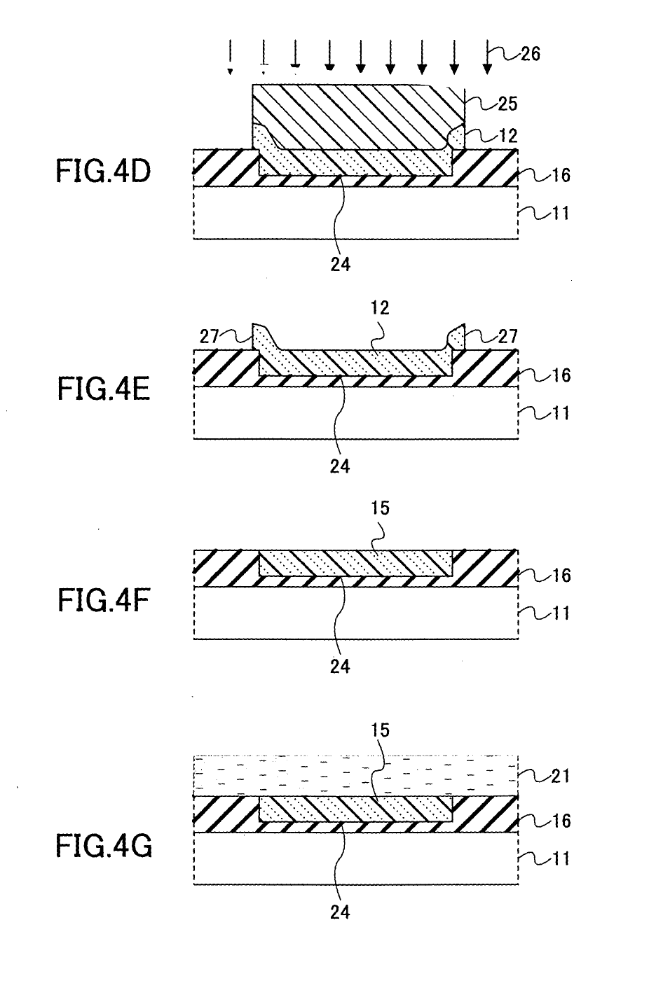

FIG. 6 illustrates the ground plane according to the fourth embodiment of the invention.

As illustrated in the cross-sectional view of FIG. 6, the ground plane 15 is formed over the PBCO thin film 29 on MgO substrate 11. To fabricate this ground plane structure, the PBCO thin film 29 with a thickness of 100 nm and YBCO thin film with a thickness of 300 nm are successively deposited over the MgO substrate 11 by sputtering. Then, the YBCO thin film is pattered into a predetermined shape to form the ground plane 15 by argon (Ar) ion milling, using a resist mask pattern (not shown).

With the ground plane structure formed over the substrate via the dielectric thin film (such as PBCO tin film) according to the fourth embodiment, the temperature distribution becomes substantially uniform in the subsequent film deposition processes for interlevel dielectric, such as LSAT, and for oxidic superconducting layer, such as YBCO, as in the first embodiment. Therefore, the same effects and advantages as in the first embodiment can be achieved.

In the fourth embodiment, the ground plane 15 does not have a buried structure. Therefore, attention has to be paid to breakout of interconnect due to level difference at the edge of the ground plane 15.

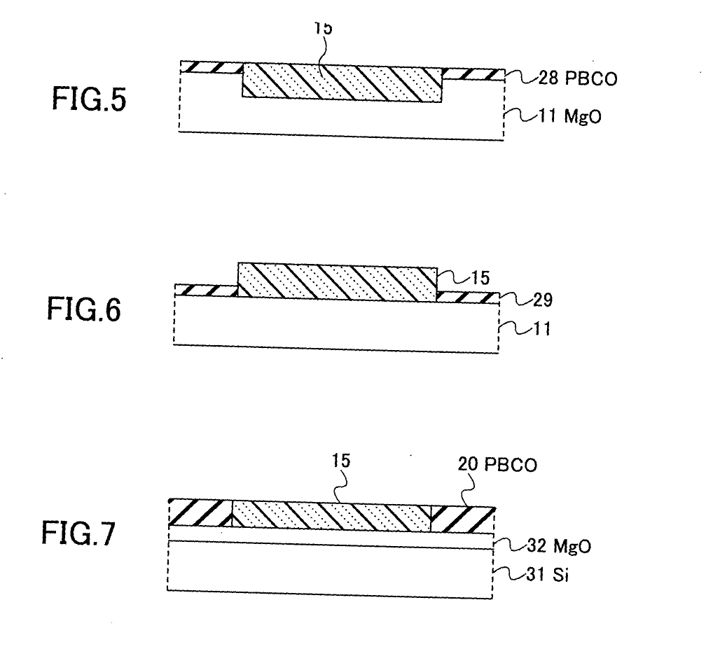

FIG. 7 illustrates the ground plane according to the fifth embodiment of the invention.

As illustrated in the cross-sectional view of FIG. 7, a buried ground plane 15 is fabricated on the layered substrate with a MgO film 32 on the silicon (Si) substrate 31.

To fabricate the buried ground plane structure according to the fifth embodiment, a MgO film 32 with a thickness of 100 nm is formed over the single crystalline silicon (Si) substrate 31 by sputtering. Then, YBCO ground plane 15 buried in PBCO layer 20 is fabricated by the process shown in FIG. 3A through 3G of the first embodiment.

In the fifth embodiment, the temperature distribution becomes substantially uniform in the subsequent film deposition processes for interlevel dielectric, such as LSAT, and for oxidic superconducting layer, such as YBCO, as in the first embodiment. Therefore, the same effects and advantages as in the first embodiment can be achieved.

Although the present invention has been described using specific embodiments, the present invention is not limited to the structures or conditions explained in these embodiments, and there are many modifications and substitutions, which are apparent to a person with an ordinary skill in the art, within the scope of the invention.

For instance, a MgO substrate having a low dielectric constant and a lattice match with YBCO is used in the above-described embodiments. However, a LSAT substrate consisting of [LaAlO₃]_{0.3}[Sr(Al, Ta)O₃]_{0.7}, which also has a low dielectric constant and a lattice match with YBCO, may be used in place of the MgO substrate.

A SrTiO₃ substrate, which also has a lattice match with YBCO, may also be used as the substrate. However, in this case, the dielectric constant is slightly higher than LSAT or MgO.

Although in the fifth embodiment a layered substrate with a MgO film over a single crystalline silicon substrate is used, a film formed on the single crystalline silicon substrate is not limited to MgO. Examples of the film of the layered substrate include, but are not limited to, CeO₂, STO, and LSAT.

In the above-described embodiments, YBa₂Cu₃O₇₋ₓ is used as the oxidic superconducting material forming the ground plane. However, the material for forming the ground plane is not limited to YBa₂Cu₃O₇₋ₓ, and other materials, such as REBa₂Cu₃O₇₋ₓ may be used. In this case, RE is selected from lanthanoid elements except for Pr and Ce. A single element or a mixture of two or more elements of lanthanoid may be used so as to satisfy the ratio RE:Ba:Cu=1:2:3.

Similarly, although in the above-described embodiments PrBa₂Cu₃O₇₋ₓ is used as the dielectric surrounding or supporting the ground plane, the dielectric material is not limited to this example. For example, PrBa₂Cu₃O₇₋ₓ containing some additive such as gallium (Ga) or cobalt (Co) may be used.

In addition, the oxidic superconducting material forming the ground plane is not limited to XBa₂Cu₃O₇₋ₓ, where X denotes yttrium (Y) or a lanthanoid element except for praseodymium (Pr) and cerium (Ce). For example, a bismuth (Bi) compound layered crystal oxidic superconducting material, such as Bi₂Sr₂Ca₁Cu₂Oₓ or Bi₂Sr₂Ca₂Cu₃Oₓ, may be used. In this case, the dielectric surrounding or supporting the ground plane is formed of a bismuth (Bi) compound layered crystal dielectric, such as Bi₂Sr₂CuOₓ.

Although, in the above-described embodiments, the YBCO layer and PBCO layer are formed by sputtering, the invention is not limited to this example, and a laser ablation method may be employed.

In the fifth embodiment, the ground plane fabricated on the layered substrate has a buried structure shown in the first embodiment. However, any of the ground plane structures of the second through fourth embodiments may be combined with the layered substrate.

Thus, because the dielectric layer surrounding or supporting the superconducting ground plane is formed of a dielectric material that has a crystal structure similar to and a heat absorbance close to the oxidic superconducting material of the ground plane, the temperature distribution on the surface of the substrate can be reduced during film deposition. This arrangement can reduce undesirable variation in physical or electrical characteristic of the thin film or the superconducting junction deposited on or fabricated over the substrate, contributing to high performance and reliable operation of the high-temperature superconducting device.

What is claimed is:

1. A high-temperature superconducting device comprising:
a substrate;
a ground plane formed on the substrate with a prescribed pattern and made of an oxidic superconducting material; and
a dielectric layer formed on the substrate so as to surround the ground plane, the dielectric layer having a crystal structure the same as the oxidic superconducting material and with a heat absorbance closer to that of the oxidic superconducting material than to that of the substrate.

2. A high-temperature superconducting device comprising:
a substrate;
a dielectric layer formed on the substrate so as to have a recess of a prescribed pattern; and
a ground plane filled in the recess and made of an oxidic superconducting material, said dielectric layer having a crystal structure the same as the oxidic superconducting material and with a heat absorbance closer to that of the oxidic superconducting material than to that of the substrate.

3. A high-temperature superconducting device comprising:
a substrate having a recess of a prescribed shape;
a ground plane filled in the recess and made of an oxidic superconducting material; and
a dielectric layer formed on the substrate in an area other than the recess so as to surround the ground plane, the dielectric layer having a crystal structure the same as the oxidic superconducting material and with a heat absorbance closer to that of the oxidic superconducting material than to that of the substrate.

4. A high-temperature superconducting device comprising:
a substrate;
a dielectric layer uniformly formed over the substrate; and
a ground plane formed on the dielectric layer with a prescribed pattern and made of an oxidic superconducting material, the dielectric layer having a crystal structure the same as the oxidic superconducting material and with a heat absorbance closer to that of the oxidic superconducting material than to that of the substrate.

5. The high-temperature superconducting device according to any one of claims 1 through 4, wherein the oxidic superconducting material is XBa₂Cu₃O₇₋ₓ, where X is selected from a group consisting of yttrium (Y), a lanthanoid element except for praseodymium (Pr) and cerium (Ce), and a combination of lanthanoid elements except for praseodymium (Pr) and cerium (Ce), and the dielectric layer is made of PrBa₂Cu₃O₇₋ₓ or additive-containing PrBa₂Cu₃O₇₋ₓ.

6. The high-temperature superconducting device according to any one of claims 1 through 4, wherein the oxidic superconducting material is a bismuth (Bi) compound layered crystal oxidic superconductor, and the dielectric layer is made of a bismuth (Bi) compound layered crystal dielectric material.

7. The high-temperature superconducting device according to any one of claims 1 through 4, wherein the substrate is made of one of MgO, SrTiO₃, and [LaAlO₃]_{0.3}[Sr(Al, Ta)O₃]_{0.7}.

8. The high-temperature superconducting device according to any one of claims 1 through 4, wherein the substrate is a layered substrate with a thin film of one of MgO, SrTiO₃, and [LaAlO₃]_{0.3}[Sr(Al, Ta)O₃]_{0.7} placed on a single crystalline silicon substrate.
